(19) United States
(12) Patent Application Publication
(10) Pub. No.: US 2004/0017779 A1
(43) Pub. Date: Jan. 29, 2004

(54) Remote equipment monitoring system with active warning function

(75) Inventors: Ming-Chuang Chen, Taipei City (TW); Wen-Shuai Liu, Taipei Hsien (TW)

Correspondence Address: BACON & THOMAS, PLLC, 625 SLATERS LANE, FOURTH FLOOR, ALEXANDRIA, VA, 22314

(73) Assignee: Moxa Technologies Co., Ltd., Taipei (TW)

(21) Appl. No.: 10/251,968

(22) Filed: Sep. 23, 2002

(30) Foreign Application Priority Data
Jul. 25, 2002 (TW) 091116630

(51) Int. Cl. G01R 31/08; G06F 11/00; G08C 15/00; H04J 1/16; H04J 3/14; H04L 1/00; H04L 12/26

(52) U.S. Cl. 370/245

(57) ABSTRACT

A remote equipment monitoring system with active warning function is constructed to include multiple remote equipments to be monitored, an Ethernet connected to the remote equipments, a remote monitor equipment installed in the Ethernet and adapted to monitor working status of the remote equipments, and an Ethernet switch installed in the Ethernet and adapted to collect working status messages of the remote equipment and forward collected working status message to the remote monitor equipment. The Ethernet switch has an event detection mechanism adapted to detect working status of the remote equipments, a processor adapted to analyze working status messages collected by the event detection mechanism, and a warning message generator controlled by the processor to generate a warning E-mail message to the remote monitor equipment when one working message judged to be the message of an abnormal working status.

### BACKGROUND OF THE INVENTION

1. Field of the Invention

The present invention relates to a remote equipment monitoring system and, more particularly, to a remote equipment monitoring system with active warning function, which uses an Ethernet switch to monitor working status of every remote equipment, and to drive a warning message generator to generate a warning E-mail message to the remote monitor equipment when one remote equipment failed.

2. Description of the Related Art

Conventionally, when monitoring working status of a remote equipment (for example, a computer or power generator), the maintenance engineer must go to the site of every equipment and then check the equipment, or install an Ethernet and a server in the Ethernet to inquire working status of every equipment regularly through the application of a program in the server.

The aforesaid remote equipment monitoring method has drawbacks. When several equipments at different places are to be monitored, the maintenance engineer will be tired from running around because he (she) must install the monitoring equipment in each place. Further, one maintenance engineer cannot review all the monitor equipment at every place at the same time. If the maintenance engineer scheduled to check the monitor equipment at every place regularly, the maintenance engineer cannot obtain the message immediately when the equipment at one place failed.

### SUMMARY OF THE INVENTION

The present invention has been accomplished under the circumstances in view. It is therefore the main object of the present invention to provide a remote equipment monitoring system with active warning function, which enables a person to monitor working status of multiple remote equipments at difference places from a remote place at the same time. It is another object of the present invention to provide a remote equipment monitoring system with active warning function, which automatically forwards a warning E-mail message to the remote monitor equipment when the equipment under monitoring failed. The remote equipment monitoring system with active warning function comprise multiple remote equipments (computers, power generators, etc.) to be monitored, an Ethernet connected to the remote equipments, a remote monitor equipment (for example, a notebook computer) linked to the Ethernet and adapted to monitor working status of the remote equipments, and an Ethernet switch installed in the Ethernet and adapted to collect working status messages of the remote equipment and forward collected working status message to the remote monitor equipment. The Ethernet switch has an event detection mechanism adapted to detect working status of the remote equipments, a processor adapted to analyze working status messages collected by the event detection mechanism, and a warning message generator controlled by the processor to generate a warning E-mail message to the remote monitor equipment when one working message judged to be the message of an abnormal working status.

### BRIEF DESCRIPTION OF THE DRAWINGS

FIG. 1 is a system block diagram of the present invention (I).

FIG. 2 is a system block diagram of the present invention (II).

FIG. 3 is an operational flow chart of the present invention.

### DETAILED DESCRIPTION OF THE PREFERRED EMBODIMENT

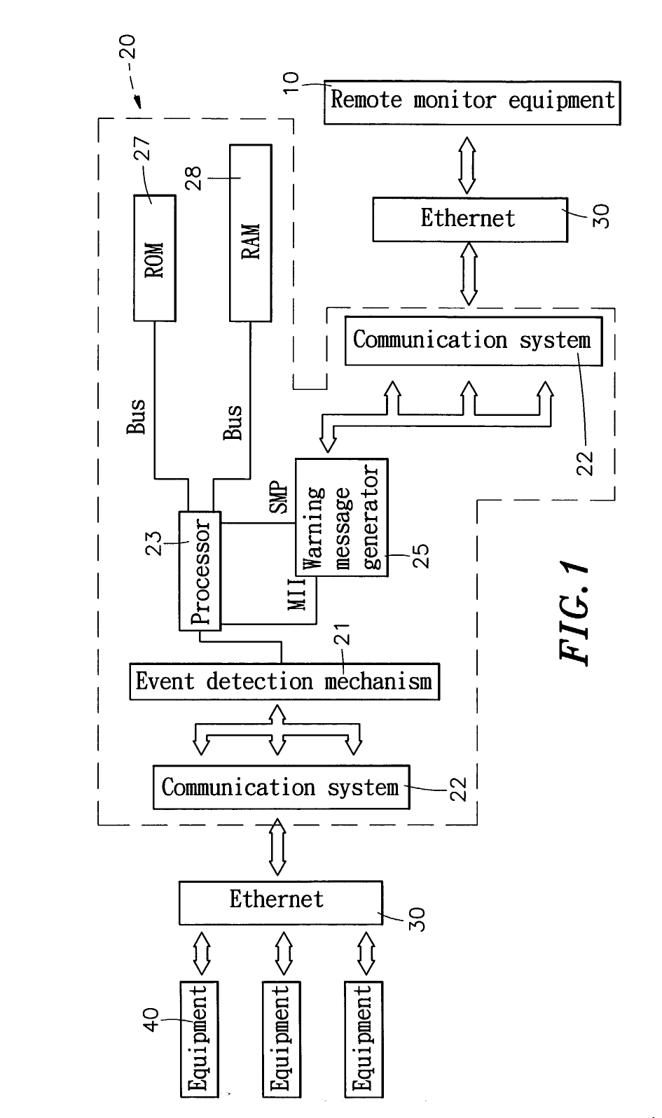

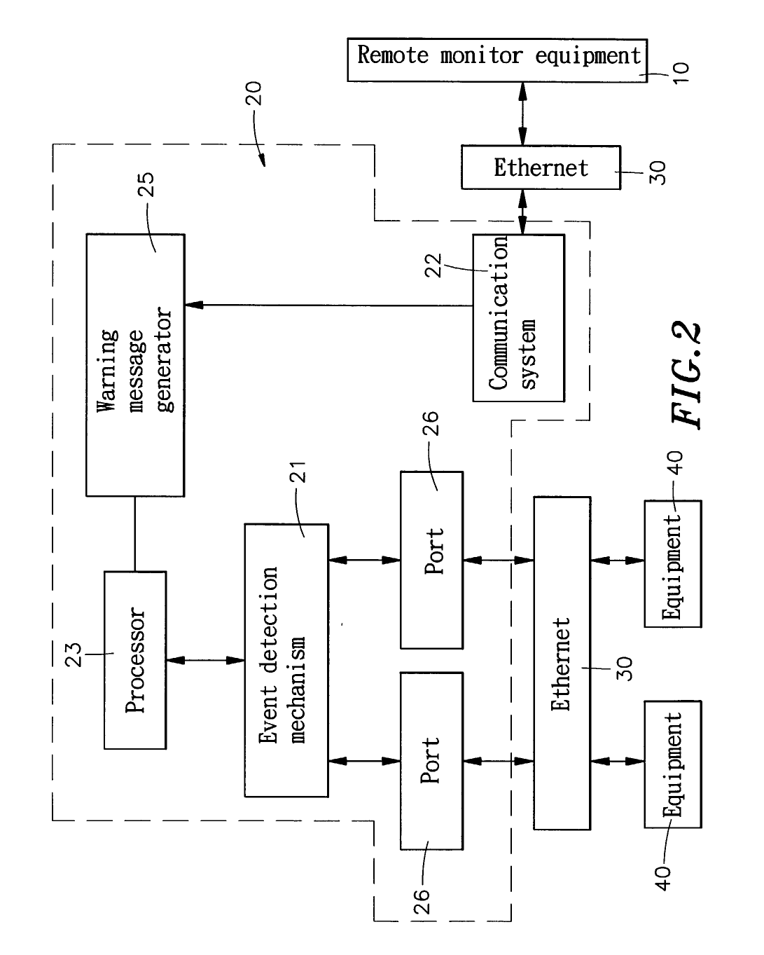

Referring to FIGS. 1 and 2, a remote equipment monitoring system with active warning function in accordance with the present invention is shown comprising an Ethernet 30 connected to the equipments (computers, power generators, etc.) 40 to be monitored, a remote monitor equipment (for example, a computer) 10 linked to the Ethernet 30 and adapted to monitor working status of the equipments 40, and an Ethernet switch 20 installed in the Ethernet 30 and connected between the equipments 40 and the remote monitor equipment 10 for transmitting packets data from the equipments 40 to the remote monitor equipment 10. The Ethernet switch 20 comprises an event detection mechanism 21 adapted to detect working status of the equipments 40, a processor (CPU) 23 adapted to receive working status messages from the equipments 40 through the event detection mechanism 21 and analyze received working status messages, a warning message generator 25 controlled by the processor 23 to generate a warning E-mail message to the remote monitor equipment 10 when one working status message received by the processor 23 judged to be the message of an abnormal status, and communication systems 22 adapted to transmit working status messages from the remote equipments 40 to the event detection mechanism 21 through the Ethernet 30 and the warning E-mail message from the warning message generator 25 to the remote monitor equipment 10 through the Ethernet 30.

The aforesaid message of abnormal status detected by the Ethernet switch 20 from the equipments 40 can be a disconnection status of one of the equipments 40 relative to the Ethernet switch 20, or a traffic jam in the Ethernet 30.

Referring to FIG. 2 again, the Ethernet switch 20 further comprises a plurality of ports 26 respectively connected to the equipments 40 and the event detection mechanism 21, for enabling the event detection mechanism 21 to detect working status of the equipments 40 actively.

Referring to FIG. 1 again, the Ethernet switch 20 further comprises a read only memory (for example, flash memory) 27 and a random access memory (for example, SDRAM) 28 respectively connected to the processor 23 through a respective bus. The processor 23 stores processing data in the random access memory 28 temporarily to facilitate time-sharing multiplex data processing, and processed storage data in the read only memory 27.

The communication systems 22 of the Ethernet switch 20 can be fiber optic converters or twisted-pair cable connectors (RJ45).

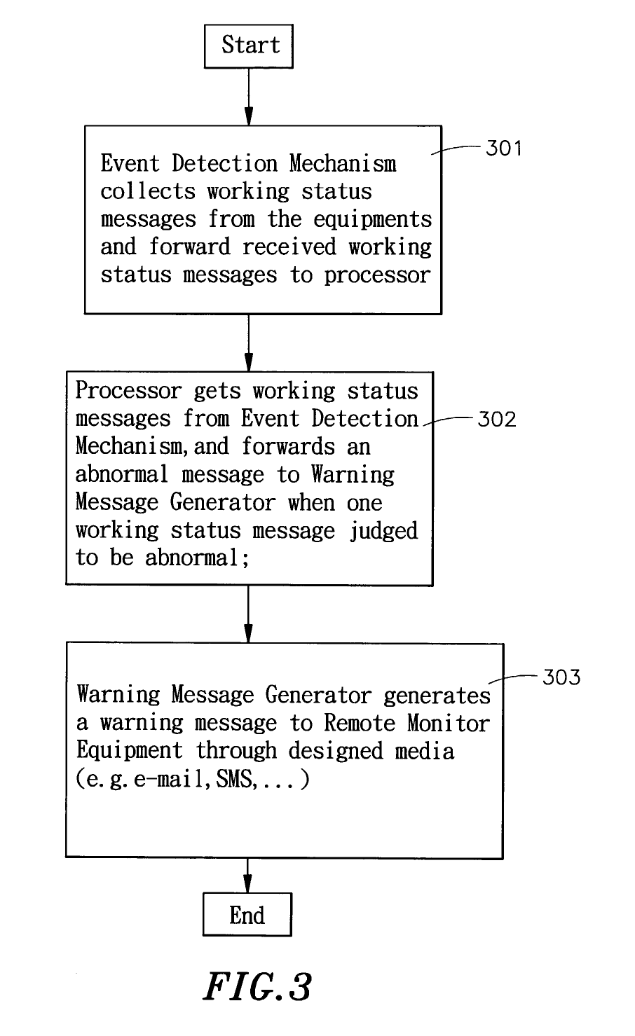

Referring to FIG. 3, when monitoring the remote equipments 40, it proceeds subject to the following steps:

(301) Event detection mechanism 21 collects working status messages from the equipments 40 and forward received working status messages to the processor 23;

(302) The processor 23 gets working status messages from the event detection mechanism 21, and forwards an abnormal message to the warning message generator 25 when one working status message judged to be abnormal;

(303) Warning message generator 25 generates a warning E-mail message to the remote monitor equipment 10 through the

Ethernet 30 via one communication system 22.

By means of the application of the present invention, one management person can monitor working status of multiple remote equipments, and send maintenance engineer to repair the equipment in trough when received a warning E-mail message.

A prototype of remote equipment monitoring system with active warning function has been constructed with the features of the annexed drawings of FIGS. 1˜3. The remote equipment monitoring system with active warning function functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A remote equipment monitoring system with active warning function, comprising at least one remote equipment to be monitored, an Ethernet connected to said at least one remote equipment to be monitored, a remote monitor equipment installed in said Ethernet and adapted to monitor working status of said at least one remote equipment, and an Ethernet switch installed in said Ethernet and adapted to collect working status messages of said at least one remote equipment and forward collected working status message to said remote monitor equipment, wherein said Ethernet switch comprises an event detection mechanism adapted to detect working status of said at least one remote equipment, a processor adapted to analyze working status messages collected by said event detection mechanism from said at least one remote equipment, and a warning message generator controlled by said processor to generate a warning E-mail message to said remote monitor equipment when one working message collected by said event detection mechanism judged by said processor to be the message of an abnormal working status.

2. The remote equipment monitoring system with active warning function as claimed in claim 1, wherein said remote monitor equipment is a computer.

3. The remote equipment monitoring system with active warning function as claimed in claim 1, wherein said at least one remote equipment is respectively a computer.

4. The remote equipment monitoring system with active warning function as claimed in claim 1, wherein said at least one remote equipment is respectively a power generator.

5. The remote equipment monitoring system with active warning function as claimed in claim 1, wherein said Ethernet switch further comprises a plurality of ports respectively connected to said event detection mechanism and said at least one remote equipment, for enabling said event detection mechanism to collect working status messages from said at least one remote equipment.

6. The remote equipment monitoring system with active warning function as claimed in claim 5, wherein said Ethernet switch further comprises a read only memory and a random access memory respectively connected to said processor, for enabling said processor to store processing data in said random access memory temporarily to facilitate time-sharing multiplex data processing, and processed storage data in said read only memory.

7. The remote equipment monitoring system with active warning function as claimed in claim 6, wherein said read only memory is a flash memory.

8. The remote equipment monitoring system with active warning function as claimed in claim 6, wherein said random access memory is a SDRAM.

9. The remote equipment monitoring system with active warning function as claimed in claim 1, wherein said communication systems of said Ethernet switch are fiber optic converters.

10. The remote equipment monitoring system with active warning function as claimed in claim 1, wherein said communication systems of said Ethernet switch are twisted-pair cable connectors (RJ45).

11. The remote equipment monitoring system with active warning function as claimed in claim 1, wherein said Ethernet switch is an Ethernet router.
